(19) United States
(12) Patent Application Publication
(10) Pub. No.: US 2006/0145597 A1
(43) Pub. Date: Jul. 6, 2006

(54) Diode matrix for controlling displays with organic diodes and production method therefor

(76) Inventor: Christoph Brabec, Linz (AT)

Correspondence Address: YOUNG & THOMPSON, 745 SOUTH 23RD STREET, 2ND FLOOR, ARLINGTON, VA, 22202, US

(21) Appl. No.: 10/536,279

(22) PCT Filed: Nov. 21, 2003
(86) PCT No.: PCT/EP03/13094

§ 371 Date: Nov. 28, 2005

(30) Foreign Application Priority Data
Nov. 29, 2002 (DE) 102 55 962.7

(51) Int. Cl. H05B 33/00; H01J 1/62

(52) U.S. Cl. 313/504

(57) ABSTRACT

The invention relates to a diode matrix for controlling displays and to a production method therefor. The diode matrix comprises at least one (partially) organic diode and can be produced, at least in part, by using printing techniques.

The invention relates to a diode matrix for controlling displays and a production method therefor, the diode matrix including at least a (partially) organic diode and being produceable, at least in part, by using printing techniques. The future of television technology is essentially based on flat-screen systems with large diagonals. At present there are flat color screens only for small screen sizes. Displays are conventionally controlled using diodes or thin-layer transistors. In the course of development work, two basic control methods have emerged: control using thinfilm transistors (TFTs) or diode control (called diode ring or MIM: metal insulation (or intrinsic) metal). With the diode matrix, the number of connections is reduced, and the production method is simpler, so it is preferred for flexible, large-area applications.

A disadvantage of the known MIM technique (see Funkschau 20/1990) is the insulation material, which in general consists of tantalum oxide (Ta₂O₅). Thus this technology is very expensive and it is difficult to implement it on a flexible film.

The object of the present invention is to create a diode or a diode matrix which shows a symmetrical characteristic for controlling displays and which at least in essential function layers consists of predominantly organic material.

The subject matter of the invention is a diode matrix with a symmetrical characteristic, which although it implements MIM technology nevertheless has an organic material in the core, as a semiconducting material. Likewise the subject matter of the invention is a diode matrix which can be produced at least in part using printing techniques. Finally the subject matter of the invention is a method for producing a diode matrix, in which at least one function layer of a diode is applied to a substrate or to a lower layer using printing techniques.

According to one embodiment an organic semiconductor is introduced into the center between two conducting function layers, whether metals or organic conductors. The resulting diode has, just as with diodes manufactured using MIM technology, a symmetrical characteristic.

Surprisingly it has been shown that even an organic semiconducting material can be used as an intermediate layer in the context of MIM technology in a matrix of diodes, each of which has a symmetrical characteristic. Unlike the known diodes with a symmetrical characteristic, here for the first time an organic material (it is important here that this material can be precipitated from solution) is used as a semiconductor material, as a result of which completely new applications of the technique become possible, because better cost-effectiveness paves the way for a further spread of the technique.

Until now the possibility of producing a complete diode matrix from organic material was unknown and largely inconceivable; this only became possible through the use of an organic semiconductor material.

The invention permits simple, low-cost control for matrix displays, in particular for OLED displays. The invention proposes implementing a diode array by means of organic diodes, in particular by means of printed organic diodes, which make a switch matrix available for controlling the display.

The term “organic diode” here includes all types of fully organic, partially organic and other diodes which have at least one function layer made from organic material.

The term “organic material” and/or “function polymer” here includes all types of organic, metal-organic and/or inorganic plastic materials, which in English are designated for example as “plastics”. This includes all types of materials with the exception of the semiconductors which form the traditional diodes (germanium, silicon), and of the typical metallic conductors. Thus the term is not restricted in the dogmatic sense to organic material as carbon-containing material; instead the widespread use of e.g. silicon is also proposed. Furthermore the term should not be subject to any restriction in respect of the molecule size, in particular of polymer and/or oligomer materials, and the use of “small molecules” is certainly also possible.

Likewise nanoparticle semiconductors should be included (such as ZnO, TiO2, CdSe, CIS nanoparticles) which can be processed out of solution.

The method to produce the diode matrix preferably entails printing techniques, with at least one function layer being applied to a substrate or a lower layer using printing techniques. The MIM unit is preferably applied using printing techniques and especially preferably the entire diode matrix is produced using printing techniques.

For the first time the invention presents a matrix made of diodes which in each case include a symmetrical characteristic and an intermediate layer which is made of a semiconducting organic material and arranged between two conducting layers. Through the use of predominantly organic materials the production costs are reduced so dramatically that completely new applications of the diode matrix are possible on a much larger scale than previously practiced.

1. Matrix of diodes, each of which includes a symmetrical characteristic in accordance with MIM (“Metal Insulator Metal”) technology and an intermediate layer which is made of a semiconducting organic material and arranged between two conducting layers.

2. Diode matrix according to claim 1, which can be produced at least in part by using printing techniques.

3. Diode matrix according to claim 1, which can be produced entirely using printing techniques.

4. Method for producing a diode matrix, which comprises applying at least one function layer of the respective diode to a substrate or a lower layer by using printing techniques.

5. Diode matrix according to claim 2, which can be produced entirely using printing techniques.
